(19) United States
(12) Patent Application Publication
(10) Pub. No.: US 2013/0001572 A1
(43) Pub. Date: Jan. 3, 2013

(54) DISPLAY DEVICE, THIN-FILM TRANSISTOR USED FOR DISPLAY DEVICE, AND METHOD OF MANUFACTURING THIN-FILM TRANSISTORS

(75) Inventors: Eiichi SATOH, Osaka (JP); Genshirou Kawachi, Osaka (JP); Takahiro Kawashima, Osaka (JP)

(73) Assignee: Panasonic Corporation, Osaka (JP)

(21) Appl. No.: 13/616,673

(22) Filed: Sep. 14, 2012

Related U.S. Application Data
(63) Continuation of application No. PCT/JP2012/001587, filed on Mar. 8, 2012.

(30) Foreign Application Priority Data
Jun. 17, 2011 (JP) 2011-134877

(51) Int. Cl. H01L 27/15; H01L 21/336

(52) U.S. Cl. 257/59; 257/72; 438/158; 257/E27.121; 257/E21.414

(57) ABSTRACT

A thin-film transistor used for a display device includes a gate electrode formed on an insulating substrate; a gate insulating film formed on the substrate so as to cover the gate electrode; a semiconductor layer composed of first semiconductor layer and second semiconductor layer formed on the gate insulating film; an ohmic contact layer formed on the semiconductor layer; and a source electrode and a drain electrode formed on the ohmic contact layer so as to be spaced from each other. The transistor further includes an etching stopper made of spin-on glass (SOG) on a channel-forming region of the semiconductor layer.

### TECHNICAL FIELD

The present invention relates to a display device such as an organic electroluminescence (EL) display device, to a thin-film transistor used for the display device, and to a method of manufacturing thin-film transistors.

### BACKGROUND ART

In recent years, organic EL display devices including current-driven organic EL elements have been receiving attention as a next-generation display device. Among them, an active-matrix-driven organic EL display device includes a field-effect transistor. As such a field-effect transistor, there is known a thin-film transistor where a semiconductor layer provided on a substrate with an insulating surface becomes a channel-forming region.

A thin-film transistor used for an active-matrix-driven organic EL display device requires at least a switching transistor for controlling timing (e.g. turning on and off) of driving an organic EL element; and a drive transistor for controlling the amount of light emitted from the organic EL element. Such thin-film transistors preferably have their superior transistor characteristics, on which various researches are being performed.

A switching transistor for instance requires the off-current to be further decreased and variations between the on- and off-currents to be reduced. A drive transistor requires the on-current to be further increased and variations in the on-current to be reduced.

Conventionally, as a channel-forming region of such a thin-film transistor, an amorphous (non-crystalline) silicon film for instance has been used; however, an amorphous silicon film has low mobility and resultantly the on-current is small. In recent years, to achieve a desirable drive performance (i.e. on-current) of a thin-film transistor, research and development have been made on crystallization of an amorphous silicon film by heat treatment using a laser beam for instance.

To use this crystallized silicon film for a thin-film transistor, after forming an ohmic contact layer on the channel-forming region, when processing the ohmic contact layer, damage to the channel-forming region remains, which undesirably deteriorate the characteristics of the thin-film transistor.

To reduce such damage, a method has been devised of forming an insulating film in a thin-film transistor (refer to patent literature 1 for instance).

In this conventional configuration, however, an ohmic contact layer directly contacts a crystallized silicon film, causing an electric field to concentrate between them, which undesirably increases the off-current.

### CITATION LIST

### Patent Literature

PTL 1 Japanese Patent Unexamined Publication No. 2007-305701

### SUMMARY OF THE INVENTION

The present invention provides a display device including a display element and a thin-film transistor for controlling light emission from the display element. The thin-film transistor includes a gate electrode formed on an insulating substrate; a gate insulating film formed on the substrate so as to cover the gate electrode; a semiconductor layer formed on the gate insulating film; an ohmic contact layer formed on the semiconductor layer; and a source electrode and a drain electrode formed on the ohmic contact layer so as to be spaced from each other. The transistor further includes an etching stopper made of spin-on glass (SOG) on a channel-forming region of the semiconductor layer.

The present invention provides a thin-film transistor used for a display device. The thin-film transistor includes a gate electrode formed on an insulating substrate; a gate insulating film formed on the substrate so as to cover the gate electrode; a semiconductor layer formed on the gate insulating film; an ohmic contact layer formed on the semiconductor layer; and a source electrode and a drain electrode formed on the ohmic contact layer so as to be spaced from each other. The transistor further includes an etching stopper made of SOG on a channel-forming region of the semiconductor layer.

The present invention provides a method of manufacturing thin-film transistors. A thin-film transistor, used for a display device, includes a gate electrode formed on an insulating substrate; a gate insulating film formed on the substrate so as to cover the gate electrode; a semiconductor layer formed on the gate insulating film; an ohmic contact layer formed on the semiconductor layer; and a source electrode and a drain electrode formed on the ohmic contact layer so as to be spaced from each other. The method includes the successive steps of: successively forming the gate electrode, the gate insulating film, and the semiconductor layer on the insulating substrate; then forming an etching stopper made of SOG on a channel-forming region of the semiconductor layer; then successively forming a film for forming the ohmic contact layer so as to cover the etching stopper and an electrode film becoming the source electrode and the drain electrode; and then forming the ohmic contact layer, the source electrode, and the drain electrode by etching.

As described above, the present invention provides thin-film transistors with stable characteristics without greatly increasing the number of processing steps.

### BRIEF DESCRIPTION OF DRAWINGS

FIG. 1 is a partial cutaway perspective view of an organic EL display device as a display device according to an embodiment of the present invention.

FIG. 2 is a circuit configuration diagram of a pixel of the display device according to an embodiment of the present invention.

FIG. 3 is a sectional view showing the structure of a device composing an organic EL element and a drive transistor in a pixel of the display device according to an embodiment of the present invention.

FIG. 4A is a sectional view showing a configuration of a thin-film transistor according to the embodiment of the present invention.

FIG. 4B is a plan view showing a configuration of the thin-film transistor according to an embodiment of the present invention.

FIG. 5A is a sectional view showing an example manufacturing process in a method of manufacturing thin-film transistors, according to the embodiment of the present invention.

FIG. 5B is a sectional view showing an example manufacturing process in the method according to an embodiment of the present invention.

FIG. 5C is a sectional view showing an example manufacturing process in the method according to an embodiment of the present invention.

FIG. 5D is a sectional view showing an example manufacturing process in the method according to an embodiment of the present invention.

FIG. 5E is a sectional view showing an example manufacturing process in the method according to an embodiment of the present invention.

FIG. 5F is a sectional view showing an example manufacturing process in the method.

FIG. 5G is a sectional view showing an example manufacturing process in the method according to an embodiment of the present invention.

FIG. 5H is a sectional view showing an example manufacturing process in the method according to an embodiment of the present invention.

### DESCRIPTION OF EMBODIMENT

### Exemplary Embodiment

Hereinafter, a description is made of a thin-film transistor (hereinafter sometimes abbreviated as TFT), and a method of manufacturing TFTs, according to an embodiment of the present invention with reference to the related drawings.

First, a description is made of a display device according to the embodiment of the present invention, taking an organic EL display device as an example.

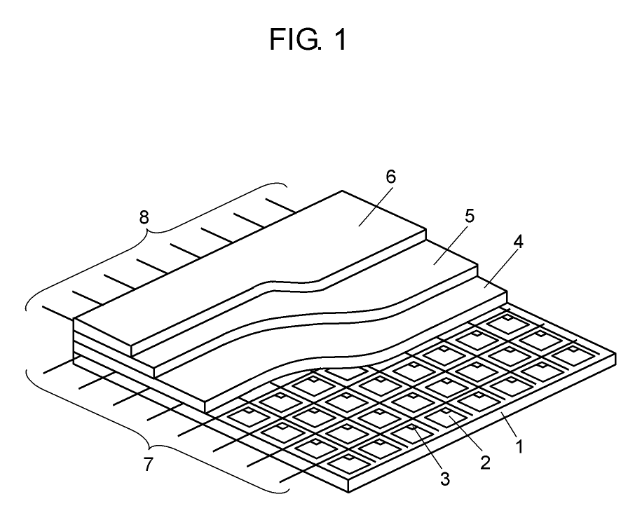

FIG. 1 is a partial cutaway perspective view of an organic EL display device as a display device according to the embodiment of the present invention, showing an outline structure of the organic EL display device. As shown in FIG. 1, the organic EL display device includes active matrix substrate 1; pixels 2 arranged in a matrix on active matrix substrate 1; pixel circuits 3 connected to pixels 2, arranged in an array on active matrix substrate 1; an EL element composed of electrode 4 as a positive electrode, organic EL layer 5, and electrode 6 as a negative electrode, each successively laminated on pixels 2 and pixel circuits 3; and source wirings 7 and gate wirings 8 for connecting respective pixel circuits 3 to a control circuit. Organic EL layer 5 of the EL element is formed by successively laminating some layers such as an electron transfer layer, a light-emitting layer, and a positive hole transfer layer.

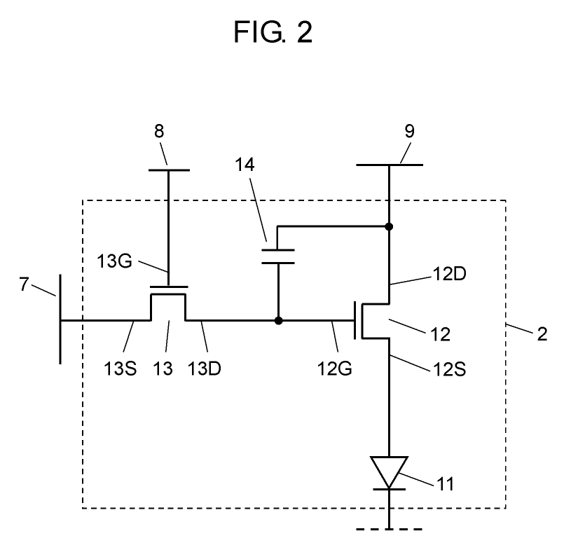

Next, a description is made of an example circuit configuration of pixel 2 using FIG. 2. FIG. 2 is a circuit configuration diagram of a pixel of a display device according to the embodiment of the present invention.

As shown in FIG. 2, pixel 2 of the display device includes organic EL element 11 as a display element; drive transistor 12 formed of a thin-film transistor for controlling the amount of light emitted from organic EL element 11; switching transistor 13 formed of a thin-film transistor for controlling timing (e.g. turning on and off) of driving organic EL element 11; and capacitor 14. Source electrode 13S of switching transistor 13 is connected to source wiring 7; gate electrode 13G is connected to gate wiring 8; and drain electrode 13D is connected to capacitor 14 and gate electrode 12G of drive transistor 12. Drain electrode 12D of drive transistor 12 is connected to power wiring 9; and source electrode 12S is connected to the anode of organic EL element 11.

In such a configuration, when a gate signal is input into gate wiring 8 and switching transistor 13 is turned on, a signal voltage corresponding to an image signal supplied through source wiring 7 is written into capacitor 14. The retaining voltage written into capacitor 14 is retained through one frame period.

The retaining voltage written into capacitor 14 changes the conductance of drive transistor 12 in an analog fashion to cause a drive current corresponding to the gradation in light emission to flow from the anode of organic EL element 11 to the cathode. The drive current running through the cathode causes organic EL to element 11 to emit light, which is displayed as an image. Consequently, as described above, the display device includes a display element and a thin-film transistor for controlling light emission from the display element.

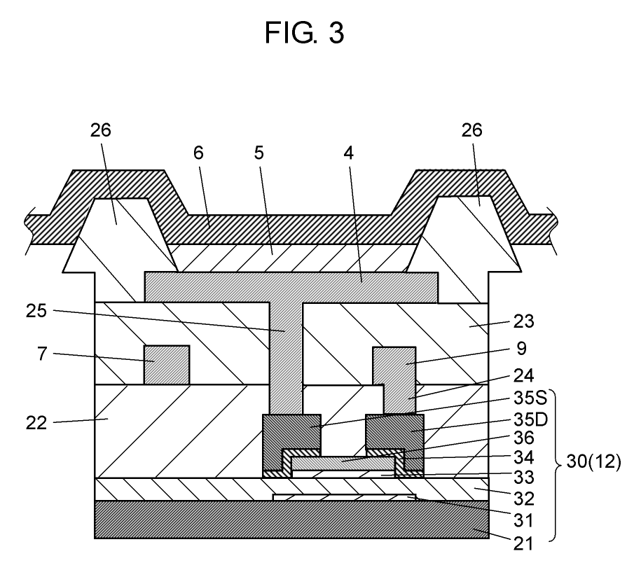

FIG. 3 is a sectional view showing the structure of a device composing an organic EL element and a drive transistor in a pixel of an organic EL display device according to the embodiment of the present invention.

As shown in FIG. 3, the organic EL display device includes first interlayer insulating film 22, second interlayer insulating film 23, first contact part 24, second contact part 25, and bank 26, all on insulating support substrate 21 that is a TFT array substrate on which drive transistors 12 and switching transistors (not shown) are formed. As described in FIG. 1, the organic EL display device further includes electrode 4 as the positive electrode at a lower side; organic EL layer 5; and electrode 6 as the negative electrode at an upper side.

Here, thin-film transistor 30 forming drive transistor 12 is a bottom-gate, n-type thin-film transistor and is formed by successively laminating gate electrode 31, gate insulating film 32, semiconductor layer 33, ohmic contact layer 34, and source electrode 35S and drain electrode 35D, on support substrate 21.

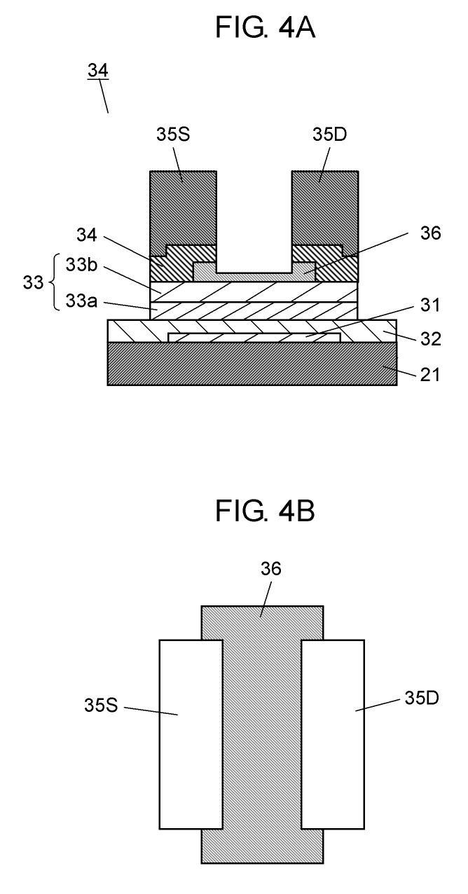

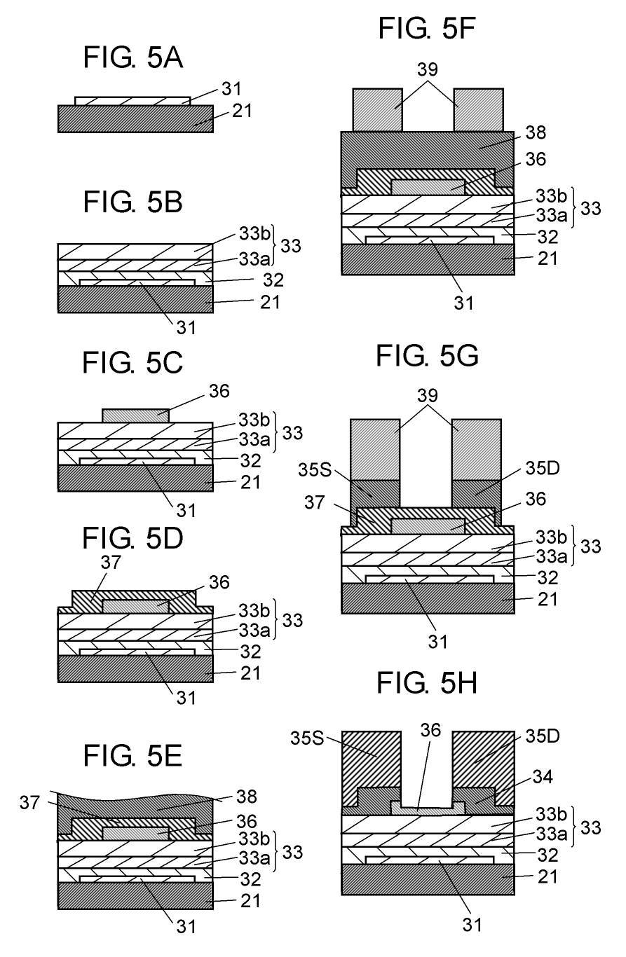

Next, a description is made of a configuration of a thin-film transistor and a method of manufacturing the transistor, according to the embodiment of the present invention using FIGS. 4A through 5H.

FIG. 4A is a sectional view showing a configuration of thin-film transistor 30 according to the embodiment of the present invention. FIG. 4B is a plan view of thin-film transistor 30 viewed from the source and drain electrodes.

As shown in FIGS. 4A and 4B, thin-film transistor 30 is a bottom-gate, n-type thin-film transistor. Thin-film transistor 30 is formed of gate electrode 31, gate insulating film 32, first semiconductor layer 33a, second semiconductor layer 33b, etching stopper 36, ohmic contact layer 34, and source electrode 35S and drain electrode 35D, each successively laminated on support substrate 21 as a substrate.

Gate electrode 31 is pattern-formed of electrode material such as molybdenum (Mo) for instance in a strip shape on support substrate 21 made of an insulating substrate such as glass. If the manufacturing process includes a heating step, gate electrode 31 is preferably made of a high-melting-point metallic material resistant to heat alteration.

Gate insulating film 32, formed so as to cover gate electrode 31, is film-formed of a lamination of at least an insulating material such as SiO₂, SiN, or SiON by plasma chemical vapor deposition (CVD) for instance in a thickness of approximately 75 nm to 500 nm.

Semiconductor layer 33 composed of source electrode 35S, drain electrode 35D, first semiconductor layer 33a, and second semiconductor layer 33b is formed on gate insulating film 32 so as to cover gate electrode 31.

Consequently, first semiconductor layer 33a laminated on gate insulating film 32 is formed of a crystalline silicon film containing crystalline silicon with a thickness of 30 nm to 500 nm. First semiconductor layer 33a may be formed by crystallizing part of a laminated semiconductor film.

Second semiconductor layer 33b, laminated on first semiconductor layer 33a, is preferably a non-crystalline silicon film with its mobility lower than that of first semiconductor layer 33a to reduce the off-current; however, second semiconductor layer 33b may be a film containing crystalline silicon. Second semiconductor layer 33b, by being formed between ohmic contact layer 34 and first semiconductor layer 33a, moderates an electric field at the drain electrode, thereby reducing the off-current.

Ohmic contact layer 34 is formed on semiconductor layer 33. Specifically, ohmic contact layer 34 is for forming contact between source electrode 35S and drain electrode 35D and semiconductor layer 33 composed of first semiconductor layer 33a and second semiconductor layer 33b, by ohmic connection, where ohmic contact layer 34 is formed of a material that is a non-crystalline silicon film with impurities doped thereinto. Examples of the impurities include a group 5 metal such as phosphorus (P) and a group 3 metal. In the examples shown in FIGS. 4A and 4B, ohmic contact layer 34 has been removed from a part other than source electrode 35S and drain electrode 35D; first semiconductor layer 33a, second semiconductor layer 33b, and ohmic contact layer 34 may remain at some parts around source electrode 35S and drain electrode 35D.

Source electrode 35S and drain electrode 35D are pattern-formed and disposed on ohmic contact layer 34 in a state spaced from each other. Source electrode 35S and drain electrode 35D are formed of a single layer made of a metal such as titanium (Ti), tantalum (Ta), molybdenum (Mo), tungsten (W), aluminum (Al), and copper (Cu); or a laminated film made of two or more layers, with a film thickness of approximately 50 nm to 1,000 nm, by sputtering for instance.

Etching stopper 36 is formed of photosensitive SOG (spin-on glass) (e.g. silsesquioxane) having a siloxane structure, on a channel-forming region of semiconductor layer 33. Etching stopper 36 is formed so as to protect a channel-forming region to prevent the transistor characteristics from fluctuating due to damage to first semiconductor layer 33a caused by penetration of etching through second semiconductor layer 33b when source electrode 35S and drain electrode 35D and ohmic contact layer 34 are etched into a given pattern. Here, Etching stopper 36 desirably has a film thickness of 300 nm or greater for reasons of fixed charge at the interface and in the film.

As described above, thin-film transistor 30, used for a display device, includes gate electrode 31 formed on insulating support substrate 21; gate insulating film 32 formed on support substrate 21 so as to cover gate electrode 31; semiconductor layer 33 formed on gate insulating film 32; ohmic contact layer 34 formed on semiconductor layer 33; and source electrode 35S and drain electrode 35D formed on ohmic contact layer 34 in a state spaced from each other.

Hereinafter, a description is made of a method of manufacturing thin-film transistors using sectional views showing an example manufacturing process. FIGS. 5A through 5H are sectional views showing an example manufacturing process in the method of manufacturing thin-film transistors according to an embodiment of the present invention.

First, as shown in FIG. 5A, gate electrode 31 is formed as a substrate on support substrate 21. The film for gate electrode 31 is formed by sputtering for instance. Pattern processing is performed by such as wet etching or dry etching using a photoresist mask.

Next, as shown in FIG. 5B, gate insulating film 32 and semiconductor layer 33 composed of first semiconductor layer 33a and second semiconductor layer 33b are formed so as to cover gate electrode 31. Forming gate insulating film 32, first semiconductor layer 33a and second semiconductor layer 33b is performed by chemical vapor deposition (CVD) for instance.

Next, as shown in FIG. 5C, etching stopper 36 is formed on the channel-forming region of semiconductor layer 33. A photosensitive SOG material (e.g. Silses Quixane) having a siloxane structure onto semiconductor layer 33 is applied to a desired thickness greater than 300 nm, and then etching stopper 36 is processed in a given pattern by photolithography so that etching stopper 36 is formed only in the channel-forming region of semiconductor layer 33.

Next, as shown in FIG. 5D, film 37 is film-formed for forming ohmic contact layer 34 so as to cover etching stopper 36 and semiconductor layer 33 by plasma CVD for instance. Further, as shown in FIG. 5E, electrode film 38 which becomes source electrode 35S and drain electrode 35D is formed on film 37 for ohmic contact layer 34. Sputtering, for instance, is used to form electrode film 38.

Then, as shown in FIG. 5F, after forming resist mask 39 on electrode film 38, as shown in FIG. 5G, electrode film 38 is processed by etching to form source electrode 35S and drain electrode 35D.

Further, as shown in FIG. 5H, film 37 for ohmic contact layer 34 and semiconductor layer 33 is processed by dry etching. At this moment, as a result that etching stopper 36 has been formed in a region where the channel of semiconductor layer 33 is formed, damage to semiconductor layer 33 is reduced. Further, using etching stopper 36 and resist mask 39 for processing allows semiconductor layer 33 and ohmic contact layer 34 to be processed at one time, thereby reducing the number of steps of manufacturing thin-film transistors.

After processing ohmic contact layer 34 and semiconductor layer 33, as shown in FIG. 5H, only resist mask 39 is removed, which provides a thin-film transistor with the configuration shown in FIGS. 4A and 4B.

As described hereinbefore, in the present invention, thin-film transistor 30 includes gate electrode 31 formed on insulating support substrate 21; gate insulating film 32 formed on support substrate 21 so as to cover gate electrode 31; semiconductor layer 33 composed of first semiconductor layer 33a and second semiconductor layer 33b formed on gate insulating film 32; ohmic contact layer 34 formed on semiconductor layer 33; and source electrode 35S and drain electrode 35D formed on ohmic contact layer 34 in a state spaced from each other. Thin-film transistor 30 further includes etching stopper 36 made of SOG on the channel-forming region of the semiconductor layer 33. Resultantly, etching stopper 36 prevents the transistor characteristics from fluctuating due to damage to first semiconductor layer 33a caused by penetration of etching through second semiconductor layer 33b when source electrode 35S and drain electrode 35D and ohmic contact layer 34 are processed by etching in a given pattern. Furthermore, using etching stopper 36 and resist mask 39 for processing allows semiconductor layer 33 and ohmic contact layer 34 to be processed at one time, thereby reducing the number of steps of manufacturing thin-film transistors.

### INDUSTRIAL APPLICABILITY

As described above, the present invention is useful for providing thin-film transistors with stable characteristics without greatly increasing the number of processing steps.

### REFERENCE MARKS IN THE DRAWINGS

21 Support substrate
30 Thin-film transistor
31 Gate electrode
32 Gate insulating film
33 Semiconductor layer
33a First semiconductor layer
33b Second semiconductor layer
34 Ohmic contact layer
35S Source electrode
35D Drain electrode
36 Etching stopper
37 Film for ohmic contact layer
38 Electrode film
39 Resist mask

1. A display device including a display element and a thin-film transistor for controlling light emission from the display element, wherein the thin-film transistor includes:
a gate electrode disposed on an insulating substrate;
a gate insulating film disposed on the substrate so as to cover the gate electrode;
a semiconductor layer disposed on the gate insulating film;
an ohmic contact layer disposed on the semiconductor layer;
a source electrode and a drain electrode disposed on the ohmic contact layer so as to be spaced from each other; and
an etching stopper made of spin-on glass (SOG) on a channel-forming region of the semiconductor layer.

2. The display device according to claim 1, wherein the etching stopper is made of SOG having a siloxane structure.

3. The display device according to claim 1, wherein the etching stopper has a film thickness of 300 nm or greater.

4. A thin-film transistor used for a display device, comprising:
a gate electrode disposed on an insulating substrate;
a gate insulating film disposed on the substrate so as to cover the gate electrode;
a semiconductor layer disposed on the gate insulating film;
an ohmic contact layer disposed on the semiconductor layer;
a source electrode and a drain electrode disposed on the ohmic contact layer so as to be spaced from each other; and
an etching stopper made of spin-on glass (SOG) on a channel-forming region of the semiconductor layer.

5. The thin-film transistor according to claim 4, wherein the etching stopper is made of SOG having a siloxane structure.

6. The thin-film transistor according to claim 4, wherein the etching stopper has a film thickness of 300 nm or greater.

7. A method of manufacturing a thin-film transistor used for a display device,
the thin-film transistor including:
a gate electrode disposed on an insulating substrate;
a gate insulating film disposed on the substrate so as to cover the gate electrode;
a semiconductor layer disposed on the gate insulating film;
an ohmic contact layer disposed on the semiconductor layer; and
a source electrode and a drain electrode disposed on the ohmic contact layer so as to be spaced from each other, the method comprising the successive steps of:
successively forming the gate electrode, the gate insulating film, and the semiconductor layer, on the insulating substrate;
then forming an etching stopper made of spin-on glass (SOG) on a channel-forming region of the semiconductor layer;
then successively forming a film to be used for forming the ohmic contact layer so as to cover the etching stopper, and an electrode film to become the source electrode and the drain electrode; and
then forming the ohmic contact layer, the source electrode, and the drain electrode by etching.

8. The method of manufacturing a thin-film transistor according to claim 7, wherein the etching stopper is made of SOG having a siloxane structure.
